(19) United States
(12) Patent Application Publication
(10) Pub. No.: US 2006/0007765 A1
(43) Pub. Date: Jan. 12, 2006

(54) Thermal recording material

(76) Inventors: Masayuki Watanabe, Tokyo (JP); Kaoru Hamada, Tokyo (JP); Junpei Natsui, Tokyo (JP); Yuji Tsuzuki, Tokyo (JP); Takashi Date, Tokyo (JP)

Correspondence Address: FLYNN THIEL BOUTELL & TANIS, P.C., 2026 RAMBLING ROAD, KALAMAZOO, MI, 49008-1631, US

(21) Appl. No.: 10/526,247

(22) PCT Filed: Aug. 28, 2003
(86) PCT No.: PCT/JP03/10960

§ 371 Date: Feb. 25, 2005

(30) Foreign Application Priority Data
Aug. 30, 2002 (JP) 2002-252279

(51) Int. Cl. G11C 7/00

(52) U.S. Cl. 365/202

(57) ABSTRACT

A thermally sensitive recording medium comprising, a thermally sensitive recording medium providing an undercoating layer containing a pigment and a binder as main components and a thermally sensitive recording layer containing a colorless or pale colored basic leuco dye and a color developing agent, which reacts with said basic leuco dye, as main components on a substrate, wherein said undercoating layer contains carboxymethyl cellulose whose etherification degree is from 0.55 to 0.75. Causing the undercoating layer to further contain hydroxyethyl cellulose from the view point of high effectiveness.

### FIELD OF THE INVENTION

The present invention relates to a thermally sensitive recording medium which utilizes coloring reaction of a basic colorless dye with an organic color developing agent.

### BACKGROUND OF THE INVENTION

In general, a thermally sensitive recording medium is prepared by following process. That is, after a colorless or pale colored basic leuco dye and an organic color developing agent are respectively ground to fine particles, these particles are mixed together with and additives such as a binder, a filler, a sensitizer and a slipping agent or others are added and obtain a coating, then the obtained coating is coated on a substrate such as a paper, a synthetic paper, a film or a plastic. The thermally sensitive recording medium develops color by instant chemical reaction caused by heating with a thermal head, a hot stamp, a thermal pen or laser beam. Usually, a thermally sensitive recording medium is broadly applied for a facsimile use, a terminal printer of a computer, an automatic bending machine for tickets and a recorder of a measuring instrument. Recently, along with the diversification or high qualification of a recording apparatus, the high speed printing and high speed image formation are becoming possible, accordingly, more excellent quality is required to the recording sensitivity of thermally sensitive recording medium. Further, along with the diversification of usage, the recorded image of high quality is required at whole range from lower density to higher density.

As a method to satisfy these requirement, the technique to improve the smoothness of the surface of thermally sensitive recording layer using a super calendar or others is ordinary carried out, however, sufficient high quality image can not be obtained. It is well known that the coating uniformity of undercoating layer is important for the formation of high quality image, for example, the improvement of smoothness of undercoating layer using a super calendar is well known. Further, in Patent Document 1, for the purpose to provide a thermally sensitive recording medium having excellent reproducibility of dot, the technique to accumulate the first intermediate layer and the second intermediate layer between a substrate and a thermally sensitive layer by order, and to adjust the OKEN smoothness of the first intermediate layer to 700 seconds or more and the density of the second intermediate layer to 0.1 or less is disclosed.

In the meanwhile, for the purpose to obtain a high sensitive thermally sensitive recording sheet, for example in Patent Document 2, there is a disclosure that two or more intermediate layers are provided between a substrate and a color developing layer and the uppermost layer contains from 0.3 wt % to 3 wt % of carboxymethyl cellulose and/or hidroxyethyl cellulose to pigment.
Patent Document 1: JPA2000-108518 publication
Patent Document 2: JPA H4-348989 publication

However, by the method using a super calendar, porous property of the under coating layer is hurt and adiabatic property is lost by calendar pressure and sensitivity is deteriorated. And the method to accumulate plural intermediate layers is not advantageous from the view point of industrial production because the process becomes complicated. Therefore, the object of the present invention is to provide a thermally sensitive recording medium which does not cause above mentioned problems, having excellent recording sensitivity and can obtain a recorded image of high quality.

### DISCLOSURE OF THE INVENTION

Said object can be dissolved by a thermally sensitive recording medium comprising, a thermally sensitive recording medium providing an undercoating layer containing a pigment and a binder as main components and a thermally sensitive recording layer containing a colorless or pale colored basic leuco dye and a color developing agent, which reacts with said basic leuco dye, as main components on a substrate, wherein said undercoating layer contains carboxymethyl cellulose whose etherification degree is from 0.55 to 0.75.

### PREFERRED EMBODIMENT OF THE INVENTION

The embodiment of the present invention will be illustrated more in detail.

The undercoating layer of the present invention contains a pigment and a binder as main components and further contains carboxymethyl cellulose. The reason why the excellent effect is obtained in the present invention is not obvious, however, is conjectured as follows.

As one reason to deteriorate the quality of image, lower concentration of solid and higher water amount in a coating for undercoating layer in thermally sensitive recording layer can be mentioned. Compared with that the solid concentration of a coating of a coated layer of ordinary coating paper for printing is from 60 to 70%, the solid concentration of a coating of a thermally sensitive recording layer is set up to the level of less than 40% for the purpose to obtain good quality and dispersability of coating, which depends on the kind of pigment and binder to be used, and when is coated on a substrate such as paper, water in the coating can easily penetrates into the substrate and causes uneven surface on the coated layer. Further, the binder migrates to lower part with water and the distribution of the binder and orientation of the pigment in the coated layer become unequal. When a thermally sensitive layer is provided on said undercoating layer and an image is recorded on said surface, thermal energy is not transferred uniformly and dot becomes irregular, consequently it is conjectured that the sensitivity and the quality of image deteriorate. On the contrary, carboxymethyl cellulose used in the present invention is conjectured to have a function to enhance the water-holding ability of the coating, can control the penetration of water into the substrate, and can contribute to the formation of uniform coated layer without uneven thickness.

Further, the inventors of the present invention have found that the etherification degree of carboxymethyl cellulose is the important factor to have influence to water-holding ability of a coating. The term of etherification degree indicates the average value of substituted degree of hydroxyl group, which cellulose has, by carboxymethyl group. The lower etherification degree carboxymethyl cellulose has, the more hydroxyl groups carboxymethyl cellulose contains, and becomes the more easily to bond with water molecule by hydrogen bond, therefore, the tendency to improve the water-holding ability of the coating is observed, however, since hydrogen bond between carboxymethyl cellulose molecules becomes strong (crystallinity is advanced) and the carboxymethyl cellulose becomes difficult to be dissolved in water, preparation of the coating becomes difficult and productivity is deteriorated. In the meanwhile, when the etherification degree is high, although the water-holding ability of coating is not good, but the solubility to water becomes good and the handling becomes easy. In the present invention, from the view point of balance of these two properties, desirable etherification degree is from 0.55 to 0.75 and more desirably from 0.55 to 0.65.

Furthermore, the higher polymerization degree of carboxymethyl cellulose causes improvement of water-holding ability, because the molecule of higher polymerization degree can take in more water in it. However, since viscosity of aqueous solution becomes high, when the polymerization degree is too high, it becomes impossible to coat or to prepare a coating. Therefore, the desirable polymerization degree of carboxymethyl cellulose is 2000 or less, and concerning water-holding ability, more desirably, is from 500 to 1500.

Concerning the amount of carboxymethyl cellulose, when the using amount of carboxymethyl cellulose is too small, it is impossible to obtain sufficient water-holding ability, and the desirable blending amount of carboxymethyl cellulose is from 0.1 weight parts to 5 weight parts to 100 weight parts of pigment, more desirably from 0.3 weight parts to 2 weight parts to 100 weight parts of pigment.

In the present invention, it is effective to contain hydroxyethyl cellulose besides carboxymethyl cellulose. It is considered that hydroxyethyl cellulose has an effect to improve the fluidity of a coating, and is conjectured to provide an undercoating layer which contribute the uniformity of the recorded image.

And, it is considered that hydroxyethyl cellulose has a function to improve the water-holding ability of a coating, and the desirable etherification degree of it is from 0.8 to 2.0, and more desirably from 1.0 to 1.5. The reason why is almost same as to that of carboxymethyl cellulose, and when the etherification degree of it is lower the water-holding ability is improved, however, the solubility to water has a tendency to be deteriorated. On the contrary, when the etherification degree of it becomes higher, the water-holding ability is deteriorated, however, the handling becomes easy because the solubility to water is improved. While, the term of etherification degree of hydroxylethyl cellulose indicates the average value of substituted degree of hydroxyl group of cellulose by ethyleneoxide.

Regarding the polymerization degree of hydroxylmethyl cellulose, the inventors of the present invention, have found that the viscosity of aqueous solution, which relates with the polymerization degree, is important. Specifically, B viscosity of 2% aqueous solution is 300 mPa·s or less, desirably is 300 mPa·s or less. When the viscosity of aqueous solution becomes too high, the preparation of a coating becomes hard. When the viscosity of aqueous solution becomes too low, generally, the polymerization degree becomes low too, therefore, it is necessary to increase the using amount for the purpose to obtain sufficient water-holding ability, and the lower limit is considered to be around 5 mPa·s.

In the present invention, the function of carboxymethyl cellulose and hydroxyethyl cellulose are considered to be basically same. Compared with carboxymethyl cellulose, hydroxyethyl cellulose has several ten times of absorbing force to clay, which is a pigment, (referring document: T. S. Young and E. Fu., Tappi J. 74(4):199(1991)), a coating forms a structural body, therefore, is superior in water-holding ability (dynamic water-holding ability) right under a blade when coated by a blade coater. Especially, in the case of a vent coating, which scrapes a coating by using a blade laying down, or a beveling coating, which scrapes a coating by using a blade turning up, pressure is loaded to the contacted part and the coating is pressed strongly against paper, therefore, water is easily dehydrated from the coating and the coating becomes solid. Consequently, scum of the coating is accumulated on the edge of blade, and becomes a cause to form striped streak (defect on a coated surface) on the coated surface. On the contrary, in the case of a coating of the present invention whose dynamic water-holding ability is high, the penetration of water to paper right under the blade becomes difficult and the solidification of the coating is prevented, therefore is excellent in coating aptitude of a bent coating or a beveling coating and can prevent the generation of defects such as streak.

In the meanwhile, compared with hydroxyethyl cellusose, since carboxymethyl cellulose is inferior in absorption to clay, exists mainly in water. Therefore, is excellent in water-holding ability before a blade (static water-holding ability). Therefore, by using carboxymethyl cellulose together with hydroxymethyl cellulose, good coated surface can be obtained and coating aptitude of coating is considered to be improved.

Further, the higher concentration of coating is desirable because the amount of coating can be decreased, however, it links to the solidification of the coating. The function of carboxymethyl cellulose and hydroxyethyl cellulose is effective in the case when the concentration of coating is high and has more easily solidification.

The amount of hydroxyethyl cellulose is desirably 0.5 weight parts to 5.0 weight parts in total amount with carboxymethyl cellulose to 100 weight parts of pigment. Desirably, 0.5 weight parts to 3.5 weight parts in total amount with carboxymethyl cellulose to 100 weight parts of pigment. When the using amount of hydroxyethyl cellulose is too small, water holding ability and fluidity are not improved sufficiently, on the contrary, when the using amount of hydroxyethyl cellulose is too high, viscosity becomes too high and the coating becomes hard. As the desirable amount of hydroxyethyl cellulose is 0.3 weight parts to 3.5 weight part to 100 weight parts of pigment.

Further, in the present invention, in the case when carboxymethyl cellulose and hydroxyethyl cellulose are used together with, it is effective to use carboxymethyl cellulose whose polymerization degree is 1000 or less. When these two are used together with, the viscosity of coating becomes too high and the operation efficiency has a tendency to be deteriorated, and the operation efficiency can be improved by making the polymerization degree of carboxymethyl cellulose smaller.

In the undercoating layer of the present invention, water soluble polymer such as starch, polyvinylalcohol, methyl cellulose, stylene or maleic anhydride, or emulsion of synthetic resin such as stylene-butadiene copolymer or acrylic acid copolymer can be contained as a binder.

At the preparation of this undercoating layer, the coating amount is from about 1 to 15 g/m² and can be prepared by applying a coating on a suitable substrate such as paper, recycled paper, plastic film or synthetic paper by means of a normal coating machine. As a coating method, well known methods such as air knife method, blade method, gravure method or roll coater method can be used, however, it is desirable to form an undercoating layer by means of a blade coating method, in particular, by means of a vent blade coating method, because by this method, high concentrated coating is possible, a coating does not penetrate into a substrate and a uniform layer can be formed.

As a pigment to be contained in the undercoating layer, (calcined) koalin, calcium carbonate, aluminium oxide, titanium oxide, magnesium carbonate, amorphous silica, aluminium silicate, magnesium silicate or calcium silicate can be mentioned. Especially, calcined kaolin whose oil absorption (based on the method prescribed in JIS K5101) is from 80 cc/100 g to 120 cc/100 g is most desirable, because excellent thermally sensitive recording medium having good balance in color developing sensitivity and quality of image can be obtained. By using said calcined kaolin, sufficient adiabatic effect is provided and sensitivity is improved, further it is considered that since a binder is not absorbed by large amount in pigment, a uniform coated layer is formed so that excellent image can be obtained. In the meanwhile, compared with spherical calcium carbonate, the use of calcined kaolin is inferior in fluidity of a coating because the shape of it is flat, further, OH (hydroxyl) group of silanol is not existing on the surface because it is calcined, and bonding force with water is weakened and water-holding ability of the coating is easily deteriorated. However, in the present invention, by the function of carboxymethyl cellulose and hydroxyethyl cellulose, the coating suitability of use of calcined kaolin is improved.

Additionally, to the undercoating layer, a dispersing agent, waxes, a thickner, a surface active agent, UV absorbing agent, an antioxidant, a water repellent agent or an oil repellent agent can be added when need is arisen.

The thermally sensitive recording layer to be formed on the undercoating layer is formed according to the conventional well known method.

As the colorless or pale colored basic leuco dye to be used in the thermally sensitive recording medium of the present invention, all public known dyes in the field of the conventional pressure sensitive or thermally sensitive recording paper can be used and is not specifically limited, however, triphenylmethane compounds, fluorane compounds, fluorene compounds or divinyl compounds can be desirably used. Specific examples of typical colorless or pale colored basic leuco dye are shown below. These colorless or pale colored basic leuco dyes can be used alone or can be used together with.

<Triphenyl methane leuco dyes>

3,3-bis(p-dimethylaminophenyl)-6-dimethylaminophthalide [another name is Crystal Violet Lactone]
3,3-bis(p-dimethylaminophenyl)phthalide [another name is Malachite Green Lactone]
   <Fluorane leuco dyes>
3-diethylamino-6-methylfluorane
3-diethylamino-6-methyl-7-anilinofluorane
3-diethylamino-6-methyl-7-(o,p-dimethylanilino)fluorane
3-dibutylamino-6-methyl-fluorane
3-dibutylamino-6-methyl-7-anilinofluorane
3-dibutylamino-6-methyl-7-(o,p-dimethylanilino)fluorane
3-dibutylamino-6-methyl-7-(o-fluoroanilino)fluorane
3-n-dipentylamino-6-methyl-7-anilinofluorane
3-(N-ethyl-N-isoamylamino)-6-methyl-7-anilinofluorane
3-(N-ethyl-N-isoamylamino)-6-chloro-7-anilinofluorane
3-cyclohexyl amino-6-chlorofluorane
   <Divinyl leuco dyes>
3,3-bis-[2-(p-dimethylaminophenyl)-2-(p-methoxyphenyl)ethenyl]-4,5,6,7-tetrabromophthalide
3,3-bis-[2-(p-dimethylaminophenyl)-2-(p-methoxyphenyl)ethenyl]-4,5,6,7-tetrachlorophthalide
3,3-bis-[1,1-bis(4-pyrrolidinophenyl)ethylene-2-yl]-4,5,6,7-tetrabromo phthalide
3,3-bis-[1-(4-methoxyphenyl)-1-(4-pyrrolidinophenyl)ethylene-2-yl]-4,5,6,7-tetrachlorophthalide
   <Others>
3-(4-diethylamino-2-ethoxyphenyl)-3-(1-ethyl-2-methylindol-3-yl)-4-azaphthalide
3-(4-diethylamino-2-ethoxyphenyl)-3-(1-octyl-2-methylindol-3-yl)-4-azaphthalide
3-(4-cyclohexylethylamino-2-methoxyphenyl)-3-(1-ethyl-2-methylindol-3-yl) -4-azaphthalide
3,3-bis(1-ethyl-2-methylindol-3-yl)phthalide
3,6-bis(diethylamino)fluorane-γ-(3′-nitro)anilinolactam
3,6-bis(diethylamino)fluorane-γ-(4′-nitro)anilinolactam
1,1-bis-[2′,2′,2″,2″-tetrakis-(p-dimethylaminophenyl)-ethenyl]-2,2-dinitril ethane
1,1-bis-[2′,2′,2″,2″-tetrakis-(p-dimethylaminophenyl)-ethenyl]-2,2-diacetyl ethane
bis-[2,2,2′,2′-tetrakis-(p-dimethylaminophenyl)-ethenyl]-methylmalonic acid dimethyl ester.

As a color developing agent used in the thermally sensitive recording media of the present invention, conventional public known color developing agent which develops color of colorless or pale colored basic leuco dye. As the specific example of the color developing agent, bisphenol A, 4-hydroxybenzoic acid esters, 4-hydroxyphthalic acid diesters, phthalic acid monoesters, bis-(hydroxyphenyl)sulfides, 4-hydroxyphenylarylsulfones, 4-hydroxyphenylarylsulfonates, 1,3-di[2-(hydroxyphenyl)-2-propyl]benzenes, 4-hydroxybenzoyloxybenzoates or bisphenolsulfones which are mentioned in Japanese Patent Laid-open Publication 3-207688 or in Japanese Patent Laid-open Publication 5-24366.

Further, same as to the conventional thermally sensitive recording medium, in the present invention, public known sensitizers can be used. As the specific example of the sensitizer,
fatty acid amide such as stearic acid amide or palmitic acid amide,
ethylenebisamide,
montan acid wax,
polyethylene wax,
1,2-di-(3-methylphenoxy)ethane,
p-benzylbiphenyl,
β-benzyloxynaphthalene,
4-biphenyl-p-tolylether,
m-tarphenyl,
1,2-diphenoxyethane,
dibenzyl benzoate,
di-(p-chlorobenzyl)benzoate,
di-(p-methylbenzyl)benzoate,
dibenzylterephthalate,
benzyl p-benzyloxybenzoate,
di-p-tolylcarbonate,
phenyl-α-naphthylcarbonate,
1,4-diethoxynaphthalene,
phenyl 1-hydroxy-2-naphthoate,
o-xylene-bis-(phenylether),
4-(m-methylphenoxymethyl)biphenyl can be mentioned,
4,4′-ethylene-bis-dibenzylbenzoate, dibenzoyloxymethane,
1,2-di(3-methylphenoxy)ethylene,
Bis[2-(4-methoxy-phenoxy)ethyl]ether and
p-phenyltoluenesulfonate can be mentioned, however, not intending to be restricted to them. These sensitizers can be used alone or can be used together with.

As an image stabilizer, which displays oil repellent effect to the recorded image,
4,4′-buthylidenebis(6-t-butyl-3-methylphenol),
2,2′-di-t-butyl-5,5′-dimethyl-4,4′-sulphonyldiphenyl,
1,1,3-tris(2-methyl-4-hydroxy-5-cyclohexylphenyl)butane or
1,1,3-tris(2-methyl-4-hydroxy-5-t-butylphenyl)butane can be added.

Furthermore, a parting agent such as fatty acid metallic salt, a slipping agent such as wax, UV absorbing agent such as bezophenone or triazol, a water repellent agent such as glyoxal, a dispersing agent, a defoamer, an oxidant and a fluorescent agent can be used.

The kinds and amount of basic leuco dye, color developing agent and other components which are used in the thermally sensitive recording medium of the present invention, are decided according to the required properties and recording suitability and not restricted, however, ordinary, 0.5 to 10 parts of color developing agent and 0.5 to 10 parts of filler to 1 part of basic leuco dye is used.

The subjected thermally sensitive recording medium can be obtained by applying the coating composed of above mentioned composition on a substrate such as paper, recycled paper, synthetic paper, film, plastic film or plastic foam film. And a composite sheet which is prepared by combining these substrate can be used as a substrate.

Basic leuco dye, color developing agent and other materials to be added by necessity are pulverized by a ball mill, an attriter or a sand grinder, or by means of an adequate emulsifying apparatus, until they are pulverized to several micron size, then add acrylic emulsion, colloidal silica and various additives according to the object and prepare a coating. The means for coating is not restricted and public known conventional methods can be used, and specifically, for example, an off machine coater with various coater such as air knife coater, rod blade coater, vent blade coater, bevel blade coater and curtain coater or an on machine coater can be voluntarily chosen and used. Among these, regarding a blade coating method, the coating amount can be controlled by a blade and is desirable because the productive efficiency is high, and is considered that the larger contacting area with paper is, the more uniform the coated surface become, the use of vent blade coating method is especially desirable in the present invention. The coating amount of the thermally sensitive layer is not restricted, and ordinary is in the range from 2 to 12 g/m² by dry weight.

Still further, the thermally sensitive recording medium of the present invention can provide an over coating layer consisting of polymer on the thermally sensitive recording layer aiming to improve preservability and can provide an under coating layer consisting of polymer containing a filler under the thermally sensitive recording layer aiming to improve the color developing sensitivity. And can provide a bag coating layer on the opposite side of the substrate to which the thermally sensitive recording is provided, for the purpose to correct the curling of the sheet. Yet further, various public known techniques in the field of the thermally sensitive recording medium can be added voluntarily, for example, to carry out a smoothness treatment such as a super calendar treatment after coating process of each layer.

### EXAMPLE

### Preparation of Thermally Sensitive Recording Medium, Example 1 and Comparative Example 1-4

The thermally sensitive recording medium of the present invention will be illustrated more actually according to the Examples and the Comparative Examples. In the Examples and the Comparative Examples, “parts” and “%” indicates “weight parts” and “weight %”. Each solution, dispersion and a coating is prepared as follows.

### Example 1

The compound consisting of blending ratio mentioned below is stirred and dispersed and a coating for undercoating layer is prepared. While, in all Examples and Comparative Examples, the concentration of coatings are fixed to around 36%.

U Solution (Coating for Undercoating Layer)

Calcined kaolin (product of Engelhard, commodity name is Ansilex

| | |
|---|---|
| 90, <oil absorbing amount is 90 cc/100 g> | 100 parts |
| Stylene·butadiene copolymer latex (solid part 48%) | 40 parts |
| Polyvinyl alcohol 10% aqueous solution | 30 parts |
| Carboxymethyl cellulose 2% solution (polymerization degree; | 25 parts |
| 500-600, etherification degree; 0.55-0.65) | |
| Water | 146 parts |

After applying the coating for undercoating layer to one surface of the substrate (paper of 100 g/m²), the object is dried and the under coating layer of 10.0 g/m² coating amount is obtained.

Dispersion of color developing agent (A solution) of following blending ratio and dispersion of basic leuco dye (B solution) are respectively ground in wet condition by a sand grinder so as the average particle size becomes to 1 micron.

| A solution (dispersion of color developing agent) | |
|---|---|
| 4-hydroxy-4′-isopropoxydiphenylsulfone | 6.0 parts |
| Polyvinyl alcohol 10% aqueous solution | 18.8 parts |
| Water | 11.2 parts |
| B solution (dispersion of basic leuco dye) | |
| 3-diethylamino-6-methyl-7-anilinofluorane (OBD-2) | 2.0 parts |
| Polyvinyl alcohol 10% aqueous solution | 4.6 parts |
| Water | 2.6 parts |

Then the dispersions are blended by following ratio and a coating for recording layer is obtained.

Coating for Recording Layer

| | |
|---|---|
| A solution (dispersion of color developing agent) | 36.0 parts |
| B solution (dispersion of basic leuco dye) | 9.2 parts |
| Kaolin clay (50% dispersion) | 12.0 parts |

The coating for recording layer is applied on the undercoating layer of the paper on which an undercoating layer is formed so as the coating amount is to be 6.0 g/m², dried and the sheet is treated by a super calendar so as the smoothness to be 500 to 600 seconds, thus a thermally sensitive recording medium is obtained.

### Example 2

A thermally sensitive recording medium is prepared by same way to Example 1 except changing the polymerization degree of carboxymethyl cellulose contained in U solution (coating for undercoating layer) to 600-800 and etherification degree of that to 0.65-0.75.

### Example 3

A thermally sensitive recording medium is prepared by same way to Example 1 except changing the polymerization degree of carboxymethyl cellulose contained in U solution (coating for undercoating layer) to 1000-1500 and etherification degree of that to 0.55-0.65.

### Example 4

A thermally sensitive recording medium is prepared by same way to Example 2 except adding 25 parts of 2% aqueous solution of hydroxyethyl cellulose whose etherification degree is 1.21 and viscosity of 2% aqueous solution is 12 mPa-s to U solution (coating for undercoating layer) and changing parts of water in U solution to 122 parts.

### Example 5

A thermally sensitive recording medium is prepared by same way to Example 4 except changing the etherification degree of hydroxyethyl cellulose contained in U solution (coating for undercoating layer) to 1.32 and viscosity of 2% aqueous solution of that to 100 mPa·s.

### Example 6

A thermally sensitive recording medium is prepared by same way to Example 4 except changing the etherification degree of hydroxyethyl cellulose contained in U solution (coating for undercoating layer) to 1.3 and viscosity of 2% aqueous solution of that to 1500 mPa-s.

### Comparative Example 1

A thermally sensitive recording medium is prepared by same way to Example 1 except not adding carboxymethyl cellulose to U solution (coating for undercoating layer).

### Comparative Example 2

A thermally sensitive recording medium is prepared by same way to Example 1 except changing the polymerization degree of carboxymethyl cellulose contained in U solution (coating for undercoating layer) to 400-500 and etherification degree of that to 1.3-1.6.

### Comparative Example 3

A thermally sensitive recording medium is prepared by same way to Example 1 except changing the polymerization degree of carboxymethyl cellulose contained in U solution (coating for undercoating layer) to 500-800 and etherification degree of that to 1.3-1.6.

<Evaluation of Recording Sensitivity>

The printing test is made on the prepared thermally sensitive recording media using TH-PMD, product of Okura Electric Co., Ltd. (printing tester for thermally sensitive recording paper, a thermal head of Kyocera Co., Ltd. is equipped), by 0.27 mJ/dot impressive energy. Recording density of printed part is measured by means of Macbeth Densitometer (RD-914, amber filter used).

<Evaluaton of printed image>

All over solid part is evaluated by visual inspection.
◯: white come off part is not observed
Δ: white come off parts are observed
X: many white come off parts are observed
   <Evaluation of Coating>

Dynamic water-holding capacity (AA dehydration amount) of the prepared coatings for undercoating layer is measured by AA-GWR water retention meter, which is the product of Kaltec Scientific Co., Ltd. Smaller value of this test, indicates higher water-holding capacity, and indicates that the water-holding ability right under the blade becomes high and a defect such as streak is not so easily generates. While the paper used for measurement is the paper whose grammage is 100 g/m².

TABLE 1

| | carboxymethyl cellulose | | hydroxyethyl cellulose | |
|---|---|---|---|---|
| | etherification | polymerization | etherification | polymerization |
| | degree | degree | degree | degree |
| Example 1 | 0.55-0.65 | 500-600 | — | — |
| Example 2 | 0.65-0.75 | 600-800 | — | — |
| Example 3 | 0.55-0.65 | 1000-1500 | — | — |
| Example 4 | 0.65-0.75 | 600-800 | 1.21 | 12 |
| Example 5 | 0.65-0.75 | 600-800 | 1.32 | 100 |
| Example 6 | 0.65-0.75 | 600-800 | 1.3 | 1500 |
| Com. | — | — | — | — |
| Ex. 1 | | | | |
| Com. | 1.3-1.6 | 400-500 | — | — |
| Ex. 2 | | | | |
| Com. | 1.3-1.6 | 500-800 | — | — |
| Ex. 3 | | | | |

Com. Ex. Comparative Example

TABLE 2

| | concentration | | |
|---|---|---|---|
| | of | AA dehydration | |
| | recorded part | amount (g/m²) | quality of image |
| Example 1 | 1.32 | 129 | ◯ |
| Example 2 | 1.33 | 118 | ◯ |
| Example 3 | 1.33 | 93 | ◯ |
| Example 4 | 1.34 | 95 | ◯ |
| Example 5 | 1.35 | 88 | ◯ |
| Example 6 | 1.35 | 63 | ◯ |
| Com. Ex. 1 | 1.31 | 208 | X |
| Com. Ex. 2 | 1.32 | 172 | Δ |
| Com. Ex. 3 | 1.32 | 155 | Δ |

### INDUSTRIAL APPLICABILITY

By the present invention, the thermally sensitive recording medium which is superior in vent blade or bevel blade aptitude of undercoating layer, having high recording sensitivity and excellent quality of image can be obtained.

1. A thermally sensitive recording medium comprising, a thermally sensitive recording medium providing an undercoating layer containing a pigment and a binder as main components and a thermally sensitive recording layer containing a colorless or pale colored basic leuco dye and a color developing agent, which reacts with said basic leuco dye, as main components on a substrate, wherein said undercoating layer contains carboxymethyl cellulose whose etherification degree is from 0.55 to 0.75.

2. The thermally sensitive recording medium of claim 1, wherein the pigment is calcined kaolin whose oil absorption by JIS K5101 is from 80 ml/100 g to 120 ml/100 g.

3. The thermally sensitive recording medium of claim 1, wherein the undercoating layer further contains hydroxyethyl cellulose.

4. The thermally sensitive recording medium of claim 3, wherein B viscosity of 2% aqueous solution of hydroxyethyl cellulose is 300 mPa·s or less.
